(19) United States
(12) Patent Application Publication
(10) Pub. No.: US 2016/0006432 A1
(43) Pub. Date: Jan. 7, 2016

(54) SEMICONDUCTOR DEVICE AND OPERATING METHOD THEREOF

(71) Applicant: SK hynix Inc., Gyeonggi-do (KR)

(72) Inventor: Kwan-Su SHON, Gyeonggi-do (KR)

(21) Appl. No.: 14/569,361

(22) Filed: Dec. 12, 2014

(30) Foreign Application Priority Data
Jul. 3, 2014 (KR) 10-2014-0083053

(51) Int. Cl. H03K 17/687

(52) U.S. Cl. CPC H03K 17/687

(57) ABSTRACT

A semiconductor device includes a plurality of impedance providing sections suitable for providing an input/output node with a first impedance corresponding to a signal transmission, and a second impedance corresponding to a signal reception, and an impedance control section suitable for adjusting the first impedance by adjusting the number of enabled impedance providing sections among the plurality of impedance providing sections during the signal transmission, and adjusting the second impedance by changing impedance of one or more impedance providing sections among the plurality of impedance providing sections during the signal reception.

### CROSS-REFERENCE TO RELATED APPLICATIONS

The present application claims priority of Korean Patent Application NO. 10-2014-0083053 filed on Jul. 3, 2014, which is incorporated herein by reference in its entirety.

### BACKGROUND

1. Field

Various exemplary embodiments of the present invention relate to a semiconductor design technology, and more particularly, to a semiconductor device capable of transmitting and receiving a signal through a transmission line.

2. Description of the Related Art

Generally, a semiconductor memory device such as a double data rate synchronous dynamic random access memory stores or outputs data in response to a command signal and an address signal received from an external controller. The command signal, address signal and data are transferred through a transmission line electrically coupled between the controller and the semiconductor memory device. In addition to the semiconductor memory device, any other circuits may transfer signals through transmission lines that are electrically coupled therebetween.

Occasionally signals are lost during the transfer through transmission lines due to various reasons. One reason signals are lost is because of impedance mismatching. Impedance mismatching causes signal reflection, which leads to signal distortion. Therefore, there is a need to control impedance for circuits transferring signals through transmission lines.

### SUMMARY

In accordance with an embodiment of the present invention, a semiconductor device may include a plurality of impedance providing sections suitable for providing an input/output node with a first impedance corresponding to a signal transmission, and a second impedance corresponding to a signal reception; and an impedance control section suitable for adjusting the first impedance by adjusting the number of enabled impedance providing sections among the plurality of impedance providing sections during the signal transmission, and adjusting the second impedance by changing impedance of one or more impedance providing sections among the plurality of impedance providing sections during the signal reception.

The plurality of impedance providing sections may have common impedance corresponding to the first impedance.

The impedance control section may adjust the command impedance of the one or more impedance providing sections during the signal reception.

Each of the one or more impedance providing sections may include a resistor having a common resistance corresponding to the common impedance; and a switching unit suitable for adjusting the amount of current flowing through the resistor during the signal reception.

A resistance of the switching unit may be smaller than the common resistance.

Each of the plurality of impedance providing sections may include a resistor having a common resistance corresponding to the common impedance; and a switching unit suitable for reflecting the common resistance to the input/output node during the signal transmission.

A resistance of the switching unit may be greater than the common resistance in impedance providing sections other than the one or more impedance providing sections, among the plurality of impedance providing sections.

The first impedance and the second impedance may be different from each other,

The one or more impedance providing sections may have a predetermined impedance value during the signal transmission, and change the impedance thereof during the signal reception.

In accordance with an embodiment of the present invention, a method of operating a semiconductor device may include adjusting a transmission impedance of an input/output node using a plurality of impedance providing sections; transmitting a signal by reflecting the transmission impedance to the input/output node; adjusting a reception impedance of the input/output node using one or more impedance providing sections among the plurality of impedance providing sections; and receiving a signal by reflecting the reception impedance to the input/output node.

The plurality of impedance providing sections may have common impedance in the adjusting of the transmission impedance.

The adjusting of the transmission impedance may include adjusting the number of enabled impedance providing sections among the plurality of impedance providing sections.

Each of the one or more impedance providing sections may comprise a switching unit suitable for adjusting the reception impedance, wherein the adjusting of the transmission impedance enables the switching unit, and wherein the adjusting of the reception impedance adjusts the amount of current flowing through the switching unit.

The adjusting of the reception impedance may include adjusting the common impedance of the one or more impedance providing sections.

The one or more impedance providing sections may comprise a plurality of switching units suitable for being enabled based on a plurality of control signals, respectively.

The adjusting of the reception impedance may include generating the control signals by performing a counting operation.

The adjusting of the transmission impedance may include setting the control signals by resetting the counting operation.

In accordance with an embodiment of the present invention, a method of operating a semiconductor device may include adjusting a transmission impedance of an input/output node by adjusting the number of enabled impedance providing sections, among a plurality of impedance providing sections having a common impedance; and adjusting a reception impedance of the input/output node by adjusting the common impedance of one or more impedance providing sections, among the plurality of the impedance providing sections.

In accordance with the embodiments of the present invention, the semiconductor device may provide an environment for a signal to be stably transferred by controlling impedance for signal communication.

Reliable signal transmission and reception may be stably performed through the control of the impedance for the signal communication.

### BRIEF DESCRIPTION OF THE DRAWINGS

FIG. 1 is a block diagram illustrating a semiconductor device in accordance with an exemplary embodiment of the present invention.

FIG. 2 is a circuit diagram illustrating first to eighth impedance providing sections shown in FIG. 1.

FIG. 3 is a flow chart illustrating an operation of signal communication of a semiconductor device shown in FIG. 1.

FIG. 4 is a block diagram illustrating a part of an impedance control section shown in FIG. 1.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete and will fully convey the scope of the present invention to those skilled in the art.

The drawings are not necessarily to scale and, in some instances, proportions may have been exaggerated in order to clearly illustrate features of the embodiments. Throughout the disclosure, reference numerals correspond directly to the like parts in the various figures and embodiments of the present invention.

It is also noted that in this specification, “connected/coupled” refers to one component not only directly coupling another component but also indirectly coupling another component through an intermediate component. In addition, a singular form may include a plural form as long as it is not specifically mentioned in a sentence. It should be readily understood that the meaning of “on” and “over” in the present disclosure should be interpreted in the broadest manner such that “on” means not only “directly on” but also “on” something with an intermediate feature(s) or a layer(s) therebetween, and that “over” means not only directly on top but also on top of something with an intermediate feature(s) or a layer(s) therebetween. When a first layer is referred to as being “on” a second layer or “on” a substrate, it not only refers to where the first layer is formed directly on the second layer or the substrate but also where a third layer exists between the first layer and the second layer or the substrate.

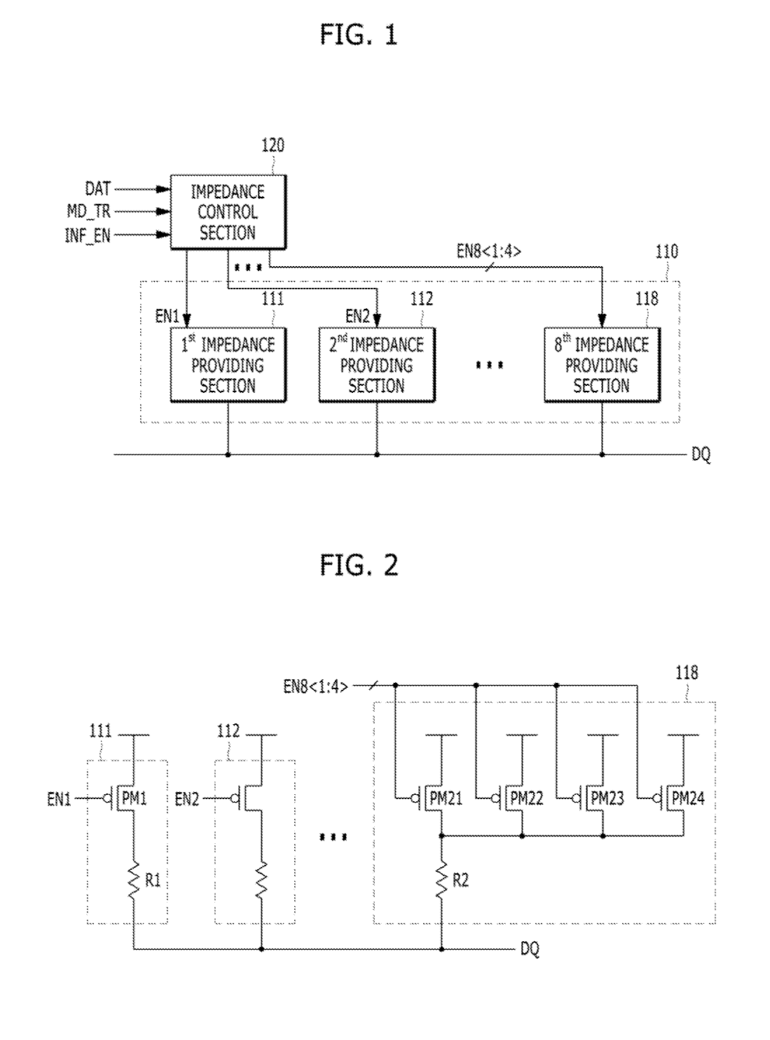

FIG. 1 is a block diagram illustrating a semiconductor device in accordance with an exemplary embodiment of the present invention.

Referring to FIG. 1, the semiconductor device may include a plurality of impedance providing sections 110, and an impedance control section 120.

The plurality of impedance providing sections 110 may provide transmission impedance corresponding to a signal transmission, and reception impedance corresponding to a signal reception to an input/output node D. For a simplified example, the semiconductor device includes eight impedance providing sections which make-up the plurality of impedance providing sections 110. In other words, the plurality of impedance providing sections 110 may comprise first to eighth impedance providing sections 111 to 118. The transmission impedance of the first to eighth impedance providing sections 111 to 118 may be set the same as one another during the signal transmission, which is referred to as common impedance. The eighth impedance providing section 118 may adjust the impedance of the input/output node DQ by adjusting the common impedance during signal reception, which will be described later,

The impedance control section 120 may adjust the impedance of the first to eighth impedance providing sections 111 to 118. Particularly, the impedance control section 120 may adjust the transmission impedance by adjusting the number of enabled impedance providing sections of the first to eighth impedance providing sections 111 to 118 during the signal transmission, and may adjust the reception impedance by controlling the eighth impedance providing section 118 during the signal reception. Although it is described that the eighth impedance providing section 118 is activated during the signal reception, another impedance providing section will do, depending on the circuit design.

The impedance control section 120 may generate first to eighth enablement control signals EN1 to EN7, and EN8<1:41> in response to data DAT, a signal transmission and reception mode signal MD_TR, and an enablement number information signal INF_EN. The signal transmission and reception mode signal MD_TR may indicate whether the semiconductor device performs the signal transmission or the signal reception, and the enablement number information signal INF_EN may indicate the number of enabled circuits during the signal transmission or the signal reception. The enablement number information signal INF_EN may indicate the number of enabled impedance providing sections of the first to eighth impedance providing sections 111 to 118 for the signal transmission, and may indicate the number of enabled PMOS transistors of a plurality of PMOS transistors included in the eighth impedance providing section 118 for the signal reception, which will be described later.

In accordance with an exemplary embodiment of the present invention, the semiconductor device may include the first to eighth impedance providing sections 111 to 118 and may adjust the transmission impedance by adjusting the number of enabled impedance providing sections of the first to eighth impedance providing sections 111 to 118 during the signal transmission. Also, the semiconductor device may adjust the reception impedance by controlling the eighth impedance providing section 118 of the first to eighth impedance providing sections 111 to 118 during the signal reception.

FIG. 2 is a circuit diagram illustrating first to eighth impedance providing sections 111 to 118 shown in FIG. 1.

Referring to FIG. 2, the first to eighth impedance providing sections 111 to 118 for providing the impedance of the input/output node DQ may be divided into pull-up impedance providing sections and pull-down impedance providing sections. The pull-down impedance providing sections are substantially the same as the pull-up impedance providing sections, and therefore, the pull-up impedance providing sections will be described for a simple description. Also, as described above, the reception impedance may be adjusted using the eighth impedance providing section 118 during the signal reception.

Each of the first to seventh impedance providing sections 111 to 117 may include a resistor and a PMOS transistor. Among the first to seventh impedance providing sections 111 to 117, the first impedance providing section 111 will be described. The first impedance providing section 111 may include a resistor R1 and a PMOS transistor PM1. The first to seventh impedance providing sections 111 to 117 may include the resistor R1 having a common resistance. The PMOS transistor PM1 may reflect the resistance of the resistor R1 to the input/output node DQ in response to the first enablement control signal EN1.

The eighth impedance providing section 118 may include first to fourth PMOS transistors PM21, PM22, PM23, and PM24, which are electrically coupled to one another in parallel, and a resistor R2 electrically coupled between the input/output node DQ and the first to fourth PMOS transistors PM21, PM22, PM23, and PM24. The first to fourth PMOS transistors PM21, PM22, PM23, and PM24 may control the amount of current flowing through the resistor R2. Each of the first to fourth PMOS transistors PM21, PM22, PM23, and PM24 may be enabled in response to the eighth enablement control signal EN8<1:4>. The amount of current flowing through the resistor R2 may depend on the enablement of each of the first to fourth PMOS transistors PM21, PM22, PM23, and PM24.

Hereinafter, the circuit will be described in detail

During the signal transmission, the enablement of each of the first to eighth impedance providing sections 111 to 118 may adjust the transmission impedance. That is, the enablement of each of the first to eighth enablement control signals EN1 to EN7 and EN8<1:4> may be determined based on the enablement number information signal INF_EN described with reference to FIG. 1, and realized in response to the data DAT. When the eighth impedance providing section 118 is determined to be enabled, all bits of the eighth enablement control signal EN8<1:4> may be enabled. As described above, the first to seventh impedance providing sections 111 to 117 may have the common resistance, and when all bits of the eighth enablement control signal EN8<1:4> are enabled, the eighth impedance providing section 118 may also have the common resistance. As such, the number of enabled impedance providing sections among the first to eighth impedance providing sections 111 to 118 may be adjusted during the signal transmission thereby adjusting the transmission impedance.

The reception impedance may be adjusted by adjusting the number of enabled PMOS transistors of the eighth impedance providing section 118 during the signal reception. That is, the first to seventh impedance providing sections 111 to 117 may not be enabled, and the enablement of each of the first to fourth PMOS transistors PM21, PM22, PM23 and PM24 of the eighth impedance providing section 118 may be determined based on the eighth enablement control signal EN8<1:4>. As such, the number of enabled PMOS transistors among the first to fourth PMOS transistors PM21, PM22, PM23, and PM24 of the eighth impedance providing section 118 may be adjusted during the signal reception thereby adjusting the amount of current flowing through the resistor R2, and adjusting the reception impedance,

In accordance with an exemplary embodiment of the present invention, the semiconductor device may adjust both of the transmission impedance and the reception impedance using the first to eighth impedance providing sections 111 to 118. Particularly the semiconductor device may set the eighth impedance providing section 118 to have the predetermined impedance during the signal transmission, and may change the impedance of the eighth impedance providing section 118 during the signal reception.

In each of the first to seventh impedance providing sections 111 to 117, the PMOS transistor PM1 may have a greater resistance than the resistor R1, thereby decreasing the impedance of each of the first to seventh impedance providing sections 111 to 117. Therefore, the first to seventh impedance providing sections 111 to 117 may control the transmission impedance of the input/output node DQ with ease when the loading of the input/output node DQ is relatively great. In the eighth impedance providing section 118, the resistor R2 may have a greater resistance than the first to fourth PMOS transistors PM21, PM22, PM23, and PM24, thereby increasing the impedance of the eighth impedance providing section 118. The eighth impedance providing section 118 may finely control the transmission impedance of the input/output node DQ with ease.

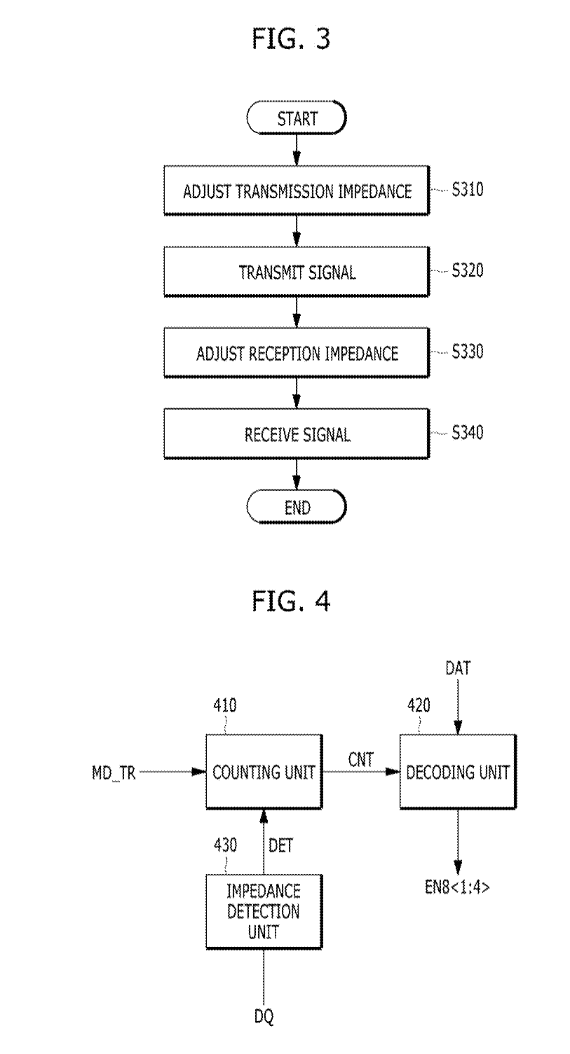

FIG. 3 is a flow chart illustrating an operation of signal communication of the semiconductor device shown in FIG. 1,

Referring to FIGS. 2 and 3, the operation of signal communication of the semiconductor device may include steps of adjusting the transmission impedance (S310), transmitting a signal (S320), adjusting the reception impedance (S330), and receiving a signal (S340).

The step S301 is the adjusting of the transmission impedance. The transmission impedance may be adjusted by adjusting the number of enabled impedance providing sections among the first to eighth impedance providing sections 111 to 118 based on the first to eighth enablement control signals EN1 to EN7 and EN8<1:4>.

The step S320 is the transmitting of the signal. The signal may be transmitted after reflection of the transmission impedance, which is adjusted at the step S310, into the input/output node DQ.

The step S330 is the adjusting of the reception impedance. The reception impedance may be adjusted by selectively enabling the first to fourth PMOS transistors PM21, PM22, PM23, and PM24 based on the eighth enablement control signal EN8<1:4>. The selective enablement of the first to fourth PMOS transistors PM21, PM22, PM23, and PM24 may adjust the amount of current flowing through the resistor R2 of the eighth impedance providing section 118, and therefore adjust the reception impedance to be reflected to the input/output node DQ.

The step S340 is the receiving of the signal. The signal may be received after reflection of the reception impedance, which is adjusted at the step S330, into the input/output node DQ.

In accordance with an exemplary embodiment of the present invention, the semiconductor device may adjust the transmission impedance by adjusting the number of enabled impedance providing sections among the first to eighth impedance providing sections 111 to 118, and adjust the reception impedance by adjusting the amount of current flowing through the first to fourth PMOS transistors PM21, PM22, PM23, and PM24 of the eighth impedance providing section 118.

The eighth enablement control signal EN8<1:4> for controlling the eighth impedance providing section 118 described with reference to FIG. 1 may be implemented in various ways. Hereinafter, one implementation of the eighth enablement control signal EN8<1:4> will be described.

FIG. 4 is a block diagram illustrating a part of the impedance control section 120 shown in FIG. 1. FIG. 4 shows the impedance control section 120 configured to operate without the enablement number information signal INF_EN described with reference to FIG. 1. FIG. 4 shows the part of the impedance control section 120 corresponding to the eighth enablement control signal EN8<1:4>.

Referring to FIG. 4, the impedance control section 120 may include a counting unit 410, a decoding unit 420, and an impedance detection unit 430.

The counting unit 410 may generate a counting signal CNT by performing a counting operation during the signal reception, and may generate the counting signal CNT having a predetermined value by resetting the counting operation during the signal transmission in response to the signal transmission and reception mode signal MD_TR.

The decoding unit 420 may generate the eighth enablement control signal EN8<1:4> in response to the data DAT and the counting signal CNT. That is, the eighth enablement control signal EN8<1:4> may have the counting value through the counting operation during the signal reception, and may have the predetermined logic value through the reset operation of the counting operation during the signal transmission. The predetermined logic value may enable all of the first to fourth PMOS transistors PM21, PM22, PM23, and PM24 of the eighth impedance providing section 118, at which the eighth impedance providing section 118 may have the value of the common impedance. That is, the eighth impedance providing section 118 may have the value of the common impedance during the signal transmission, and may change the value of the common impedance based on the eighth enablement control signal EN8<1:4>, which is counted during the signal reception.

The impedance detection unit 430 may generate a detection signal DET by detecting the impedance of the input/output node DQ during the signal reception, and provide the detection signal DET to the counting unit 410. In other words, the counting unit 410 may perform the counting operation, thereby generating the eighth enablement control signal EN8<1:4>. The reception impedance of the input/output node DQ may be adjusted based on the eighth enablement control signal EN8<1:4>. The impedance detection unit 430 may stop the counting operation of the counting unit 410 by detecting the predetermined reception impedance reflected to the input/output node DQ.

In accordance with an exemplary embodiment of the present invention, the semiconductor device may control the reception impedance through the counting operation of the counting unit 410 during the signal reception, and may control the transmission impedance through the reset operation of the counting unit 410 during the signal transmission.

As described above, in accordance with an exemplary embodiment of the present invention, the semiconductor device may adjust the transmission impedance by adjusting the number of enabled impedance providing sections among the first to eighth impedance providing sections 111 to 118, and adjust the reception impedance by adjusting the amount of current flowing through the first to fourth PMOS transistors PM21, PM22, PM23, and PM24 of the eighth impedance providing section 118.

While the present invention has been described with respect to the specific embodiments, it will be apparent to those skilled in the art that various changes and modifications may be made without departing from the spirit and scope of the invention as defined in the following claims.

The disposition and the type of the logic gates and the transistors described above may be implemented differently depending on the polarity of signals inputted thereto.

What is claimed is:

1. A semiconductor device comprising:
a plurality of impedance providing sections suitable for providing an input/output node with a first impedance corresponding to a signal transmission, and a second impedance corresponding to a signal reception; and
an impedance control section suitable for adjusting the first impedance by adjusting the number of enabled impedance providing sections among the plurality of impedance providing sections during the signal transmission, and adjusting the second impedance by changing impedance of one or more impedance providing sections among the plurality of impedance providing sections during the signal reception.

2. The semiconductor device of claim 1, wherein the plurality of impedance providing sections have common impedance corresponding to the first impedance.

3. The semiconductor device of claim 2, wherein the impedance control section adjusts the command impedance of the one or more impedance providing sections during the signal reception.

4. The semiconductor device of claim 2, wherein each of the one or more impedance providing sections comprises:
a resistor having a common resistance corresponding to the common impedance; and
a switching unit suitable for adjusting the amount of current flowing through the resistor during the signal reception.

5. The semiconductor device of claim 4, wherein a resistance of the switching unit is smaller than the common resistance.

6. The semiconductor device of claim 2, wherein each of the plurality of impedance providing sections comprises:
a resistor having a common resistance corresponding to the common impedance; and
a switching unit suitable for reflecting the common resistance to the input/output node during the signal transmission.

7. The semiconductor device of claim 6, wherein a resistance of the switching unit is greater than the common resistance in impedance providing sections other than the one or more impedance providing sections, among the plurality of impedance providing sections.

8. The semiconductor device of claim 1, wherein the first impedance and the second impedance are different from each other.

9. The semiconductor device of claim 1, wherein the one or more impedance providing sections have a predetermined impedance value during the signal transmission, and change the impedance thereof during the signal reception.

10. A method of operating a semiconductor device comprising:
adjusting a transmission impedance of an input/output node using a plurality of impedance providing sections;
transmitting a signal by reflecting the transmission impedance to the input/output node;
adjusting a reception impedance of the input/output node using one or more impedance providing sections among the plurality of impedance providing sections; and
receiving a signal by reflecting the reception impedance to the input/output node.

11. The method of claim 10, wherein the plurality of impedance providing sections have common impedance in the adjusting of the transmission impedance.

12. The method of claim 10, wherein the adjusting of the transmission impedance includes:
adjusting the number of enabled impedance providing sections among the plurality of impedance providing sections.

13. The method of claim 10,
wherein each of the one or more impedance providing sections comprises a switching unit suitable for adjusting the reception impedance,
wherein the adjusting of the transmission impedance enables the switching unit, and
wherein the adjusting of the reception impedance adjusts the amount of current flowing through the switching unit.

14. The method of claim 11, wherein the adjusting of the reception impedance includes:
adjusting the common impedance of the one more impedance providing sections.

15. The method of claim 10, wherein the one or more impedance providing sections comprises a plurality of switching units suitable for being enabled based on a plurality of control signals, respectively.

16. The method of claim 15, wherein the adjusting of the reception impedance includes:
generating the control signals by performing a counting operation.

17. The method of claim 16, wherein the adjusting of the transmission impedance includes:
setting the control signals by resetting the counting operation.
